(19) United States
(12) Patent Application Publication
(10) Pub. No.: US 2026/0013270 A1
(43) Pub. Date: Jan. 8, 2026

(54) PHOSPHOR PROTECTION IN MICROLED DISPLAYS

(71) Applicant: VueReal Inc., Waterloo (CA)

(72) Inventors: David HWANG, Kitchener (CA); Hossein Zamani SIBONI, Waterloo (CA); Gholamreza CHAJI, Kitchener (CA)

(73) Assignee: VueReal Inc., Waterloo, ON (CA)

(21) Appl. No.: 19/112,498

(22) PCT Filed: Oct. 6, 2023
(86) PCT No.: PCT/IB2023/060061

§ 371 Date: Mar. 17, 2025

Related U.S. Application Data
(60) Provisional application No. 63/413,708, filed on Oct. 6, 2022.

(51) Int. Cl. H10H 20/01

(52) U.S. Cl. CPC H10H 20/0361; H10H 20/034; H10H 20/0362; H10H 20/0363

(57) ABSTRACT

The present invention solves issues with microLED displays that use phosphors. A method to protect phosphor functionality in microLED displays during lamination includes depositing a protective bank with a transparent material before a phosphor coating. The method further includes having the protective bank acting as a barrier, so a top of the phosphor is below a top of the protective bank.

### CROSS-REFERENCE TO RELATED APPLICATIONS

This application claims the benefit of, and priority to, U.S. Provisional Patent Application No. 63/413,708 filed on Oct. 6, 2022, which is hereby incorporated by reference herein in its entirety.

### BACKGROUND AND FIELD OF THE INVENTION

The present invention relates to microLED displays that use phosphors.

### SUMMARY

The present invention relates to a method to protect a phosphor functionality in microLED display during lamination, the method comprising, having a display populated with microLEDs, adding color conversion layers on a top of microLED devices, covering the microLEDs with a passivation layer prior to a color conversion layer, depositing a protective bank with a transparent material before a phosphor coating and having the protective bank acting as a barrier so a top of the phosphor coating is below a top of the protective bank.

The present invention relates to a method to protect a phosphor functionality in microLED display during lamination, the method comprising, having a microLED display, depositing a transparent material coated on top of an entire active area after a phosphor coating, and having the transparent material acting as a physical barrier between a glass or filler interlayer and the phosphor coating.

### BRIEF DESCRIPTION OF DRAWINGS

The foregoing and other advantages of the disclosure will become apparent upon reading the following detailed description and upon reference to the drawings.

FIG. 1 shows the issue to be resolved.

FIG. 2 shows a microLED display sandwiched between glass and PVB layers.

FIG. 3(a) shows a cross section with a microLED display with a protective bank.

FIG. 3(b) shows a top view of a microLED display with a protective bank.

FIG. 4(a) shows a cross section with a microLED display with a transparent material coating.

FIG. 4(b) shows a top view of a microLED display with a transparent material coating.

### DETAILED DESCRIPTION

MicroLED displays can be used for automotive (windshield, windows, sunroof), retail (windows, large glass shelves), signage, and general glass.

MicroLED displays that use phosphors and need to be laminated between glass face an issue where the color point shifts.

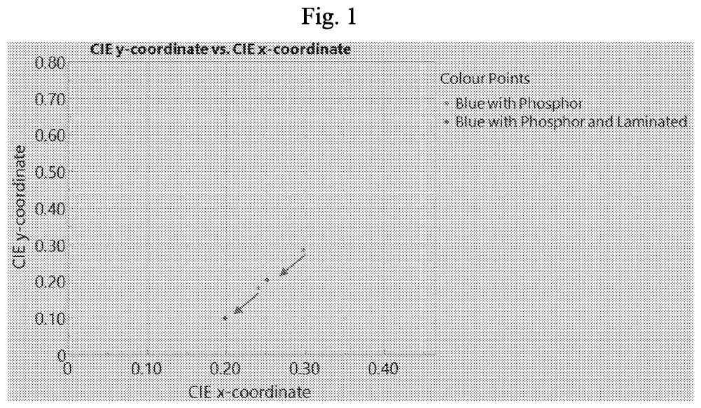

As shown in FIG. 1, red arrows show the issue to be resolved. The phosphor's ability to convert blue light to white is reduced during the lamination problem so the display no longer shows the correct color.

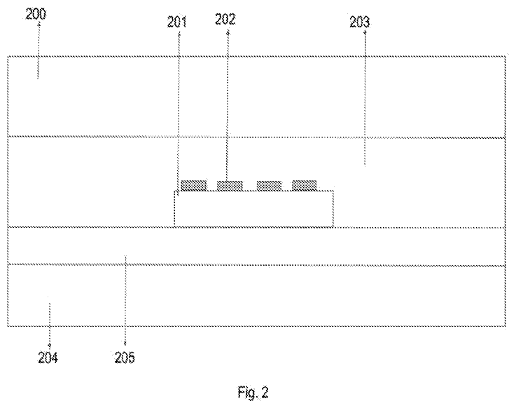

In FIG. 2, the lamination stack is shown. The display is being populated with microLED or other microdevices. Color conversion devices are added to the top of the microLED (or other microdevices). The color conversion can be phosphor or Qdot (quantum dot). The microLED can be covered with a passivation layer prior to the color conversion layer. The microLED display 201 is sandwiched between glass layers 200 and 204 and filler layers 203 and 205 (the filler layer can be PVB). During the lamination process, the phosphor 202 will come in contact with the top filler layer or glass. Pressure is applied, which squeezes the phosphor layer (makes it thinner) and degrades the optical properties (causes a color shift).

Here phosphor is used as an example of color conversion, but it can be another material as well.

When pressure and temperature are applied to the lamination stack, the filler layer and/or glass press on the phosphor 202, which causes it to thin down and reduce the number of phosphor particles that participate in down-conversion. Therefore, the resulting color is blue-shifted. To prevent that, there can be solutions that reduce or eliminate the pressure on the phosphor that may be implemented.

In one embodiment a protective bank is used (transparent material) that can act as a barrier, so the top of the phosphor is below the top of the protective bank. The protective bank will act as a spacer so the phosphor is physically protected from the lamination stack (glass, filler layers).

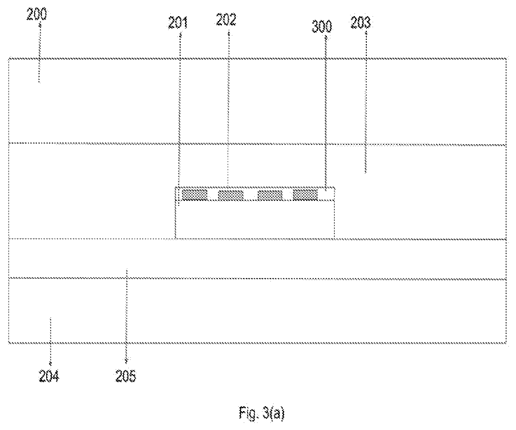

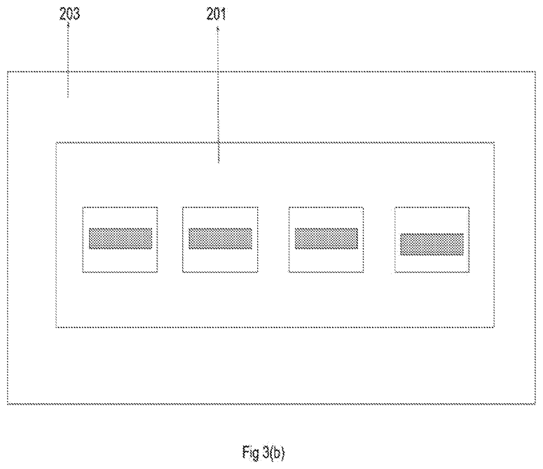

As shown in FIGS. 3(a) and 3(a) the protective bank 300 (transparent material) can be deposited on the microLED display 201 before or after phosphor coating 202. This bank will be higher than the total height of the phosphor, so when the phosphor is applied, it will sit below the bank. Therefore, when the display is laminated, the phosphor is below the top of the bank and thus physically protected.

There can be a reflective layer under the microLEDs. A passivation layer can cover microLED. The passivation layer can be patterned or a blanket layer covering the surface of the displays. A bank can be photosensitive material that is patterned around the microLED. In one case the bank is a blanked layer with an opening on top of microLEDs. Since the bank can be a thick layer, this can lead to light loss in the bank layer. In another case, the bank can be an isolated structure with walls around the microLED. The angle of the walls can be negative to direct the light to the surface. In another related embodiment, one or more of the outside surface of the wall is covered by a reflective layer. In another related embodiment, one or more of the inside wall is covered by a reflective layer. This will improve the light coupling into phosphor. Also, it will direct the light to a specific direction.

The bank layer can be patterned and hard baked to provide for better barriers.

In another related embodiment the phosphor can be covered with a thick layer of transparent material, so the lamination stack does not physically affect the phosphor.

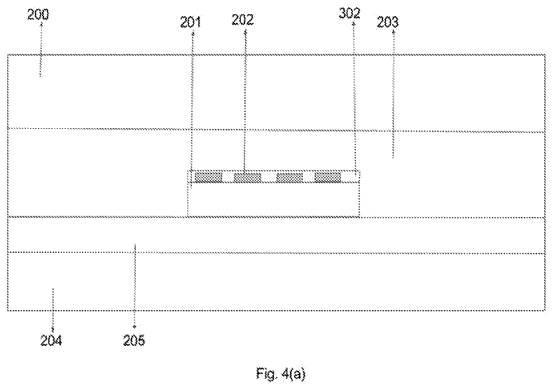

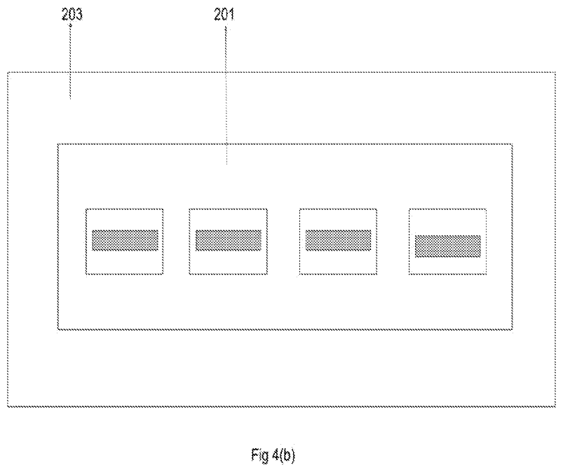

As shown in FIGS. 4(a) and 4(b) a transparent material 302 (e.g., SU8, photoresist, BCB) can be coated on top of the entire active area after the phosphor coating. In another related embodiment, the material is patterned on top of the microLEDs or phosphor area. The protection layer can be extended over the phosphor layer. This material will form a physical barrier between the glass or filler interlayer and the phosphor. When the pressure is applied on the lamination stack, the phosphor will not be thinned out or degraded.

In case the protective material 302 is patterned, one or more of the wall can be covered by reflective layers. Also, the wall of the patterned structure can have an angle to help with light extraction or light coupling.

While the present disclosure is susceptible to various modifications and alternative forms, specific embodiments or implementations have been shown by way of example in the drawings and will be described in detail herein. However, it should be understood that the disclosure is not intended to be limited to the particular forms disclosed. Rather, the disclosure is to cover all modifications, equivalents, and alternatives falling within the spirit and scope of the invention as defined by the appended claims.

1. A method to protect a phosphor functionality in a microLED display during lamination, the method comprising:
having a display populated with the microLEDs;
adding color conversion layers on a top of microLED devices;
covering the microLEDs with a passivation layer prior to a color conversion layer;
depositing a protective bank with a transparent material before a phosphor coating; and
having the protective bank acting as a barrier so a top of the phosphor coating is below a top of the protective bank.

2. The method of claim 1, wherein the display is sandwiched between glass layers and filler layers.

3. The method of claim 1, wherein the color conversion is a phosphor or a Qdot.

4. The method of claim 2, wherein the filler layer is PVB.

5. The method of claim 1, wherein the protective bank is deposited on the display before or after phosphor coating with the protective bank being higher than a total height of the phosphor coating, so when the phosphor coating is applied, it will sit below the protective bank.

6. The method of claim 1, wherein there is a reflective layer under the microLED's.

7. The method of claim 6, wherein the passivation layer is patterned, and a bank layer of a photosensitive material is patterned around the microLEDs.

8. The method of claim 7, wherein the bank layer is a blanked layer with an opening on the top of microLEDs.

9. The method of claim 7, wherein the bank layer is an isolated structure with walls around the microLED wherein an angle of the walls is negative to direct a light to a surface.

10. The method of claim 9, wherein one or more of outside surfaces of the wall is covered by a reflective layer.

11. The method of claim 9, wherein one or more of inside walls is covered by a reflective layer.

12. A method to protect phosphor functionality in a microLED display during lamination, the method comprising:
having the microLED display;
depositing a transparent material coated on top of an entire active area after a phosphor coating; and
having the transparent material acting as a physical barrier between a glass or filler interlayer and the phosphor coating.

13. The method of claim 12, wherein the transparent material is patterned on top of the microLEDs and the transparent material is extended over the phosphor coating.

14. The method of claim 12, wherein the transparent material is one of SU8, photoresist, or BCB.

15. The method of claim 13, wherein the one or more walls are covered by reflective layers. and a wall of the patterned structure has an angle to enhance light extraction or light coupling.
